(19) United States
(12) Patent Application Publication
(10) Pub. No.: US 2011/0285402 A1
(43) Pub. Date: Nov. 24, 2011

(54) METHOD AND SYSTEM FOR NON-DESTRUCTIVE DETECTION OF COATING ERRORS

(76) Inventors: Tillmann Dörr, Bremen (DE); Theo Hack, Hohenkirchen-Siegertsbrunn (DE); Christoph Schulz, Iserlohn (DE); Ralf Feser, Iserlohn (DE)

(21) Appl. No.: 13/121,299

(22) PCT Filed: Sep. 30, 2009
(86) PCT No.: PCT/EP09/62653

§ 371 Date: Jun. 22, 2011

(30) Foreign Application Priority Data
Oct. 2, 2008 (DE) 10 2008 042 570.2

(51) Int. Cl. G01R 31/02

(52) U.S. Cl. 324/551

(57) ABSTRACT

The present invention relates to a method and a measuring arrangement for the non-destructive detection of coating errors in an electrically conductive substrate layer, which is coated with at least one electrically insulating cover layer. An input signal is inductively or capacitively input into the electrically conductive substrate layer by means of a signal input device. A measurement signal is output from the substrate layer via the cover layer by means of a signal output device. An evaluation unit is used to evaluate the output measurement signal. In this case, a coating error is detected when a signal parameter change of a signal parameter of the output measurement signal exceeds an adjustable threshold value.

### CROSS-REFERENCE TO RELATED APPLICATIONS

This application claims the benefit of German Patent Application No. 10 2008 042 570.2, filed Oct. 2, 2008, the entire disclosures of which is herein incorporated by reference.

### FIELD OF THE INVENTION

The invention relates to a method and a measuring arrangement for the non-destructive detection of coating errors in an electrically conductive substrate layer, which is coated with at least one electrically insulating cover layer.

Electrically conductive substrate layers, which, for example, consist of metal or a carbon fibre-reinforced plastics material, are coated with an electrically insulating cover layer to protect them, for example, against corrosion. In this case, the cover layer forms a passive corrosion protection, which prevents corrosive materials from reaching the substrate layer and causing chemical or electrochemical reactions there. The electrically insulating cover layer may have different defects, for example pores, cracks, bubbles or the like. If these coating defects remain undiscovered, the underlying electrically conductive substrate may corrode. If these are non-metallic substrates, electrochemical reactions occur there, which can trigger contact corrosion in the case of contact with base metals.

Inductive and capacitive measuring methods are therefore used, which are based on the fact that as the spacing of the measuring head increases, its inductivity or its capacitance is changed. This inductivity or capacitance change is then converted into a spacing or layer thickness value. Conventional inductive and capacitive methods of this type are not suitable, however, for detecting smaller defects on the surface of the coating or the cover layer, even if a sufficiently small detector or measuring head is used. The detector heads used in these conventional measuring methods have the drawback that they have to rest flat on the cover layer and even very slight tilting of the measuring head leads to a drastic signal change. These known inductive and capacitive measuring methods can therefore not be used, even if they employ miniaturised detector heads, for example about 100 μm in size, to detect defects, for example in the order of magnitude of a few micrometres.

A further conventional method for measuring layer thickness uses a high voltage to test cover layers. Arcing occurs at a damaged point or at a defect because of the high voltage applied. The drawback of this method is that the electrically conductive substrate layer has to be electrically conductively connected to the high voltage source when the high voltage is applied. A further drawback of this conventional measuring method is that it does not work in a non-destructive manner. If a weak point or a defect is present in the electrically insulating cover layer, this defect is further enhanced because of the measurement, or the insulating cover layer to be measured is completely ruptured.

### SUMMARY OF THE INVENTION

It is therefore an object of the present invention to provide a method and a measuring arrangement which allow even the smallest coating errors to be detected in a safe, reliable and non-destructive manner.

The invention provides a method for the non-destructive detection of coating errors in an electrically conductive substrate layer, which is coated with at least one electrically insulating cover layer, comprising the steps:
a) inputting an input signal into the substrate layer;
b) outputting a measurement signal from the substrate layer via the cover layer; and
c) detecting a coating error when a signal parameter change of a signal parameter of the output measurement signal exceeds an adjustable threshold value.

The method according to the invention works in a non-destructive manner, i.e. this coating error is not additionally increased at an existing weak point of the electrically insulating cover layer or at a defect of the cover layer. This also means that a subcritical coating error is not transformed into a critical coating error as a result of the measurement.

A further advantage of the measuring method according to the invention is that no direct contact is required with the electrically conductive substrate layer. This is particularly important when the coating or the electrically insulating cover layer completely surrounds the component to be measured, so direct contacting of the electrically conductive substrate layer is only possible after mechanical damage to the cover layer. This mechanical damage would then have to be repaired.

The measuring method according to the invention permits inputting of an input signal through the cover layer or the coating and the input signal can therefore be applied at any point on the component without the coating or the cover layer being impaired.

In one embodiment of the method according to the invention, the measurement signal is output by means of flexible and electrically conductive bristles, which are guided over the surface of the insulting cover layer.

In this case, the flexible, electrically conductive bristles are preferably moistened with an electrolytic liquid or an auxiliary electrolyte.

In one embodiment of the method according to the invention, the input signal is capacitively or inductively input into the electrically conductive substrate layer.

In a further embodiment of the method according to the invention, the input signal is formed by a pulsed direct voltage signal.

In a possible embodiment of the method according to the invention, the input signal is formed by an alternating voltage signal with an adjustable frequency.

This alternating voltage signal is, for example, a sinusoidal alternating voltage signal with an adjustable signal frequency.

In a possible embodiment of the method according to the invention, the coordinates of a detected coating error are detected.

In a further embodiment of the method according to the invention, the type of coating error is determined.

In an embodiment of the method according to the invention, it is detected whether the coating error is formed by a hole, which extends through to the substrate layer, by a hole in the cover layer, which does not extend through to the substrate layer, or by an elevation of the cover layer.

In a possible embodiment of the method according to the invention, the respective coating error is then repaired automatically as a function of the type of coating error detected.

In one embodiment of the method according to the invention, for repair, a hole detected in the cover layer is filled in and a recognised elevation in the cover layer is removed.

In a possible embodiment of the method according to the invention, the electrolytic liquid is deionised water.

Deionised water has the advantage that, on the one hand, it still has sufficiently high conductivity and, on the other hand, after evaporation, it leaves behind no visible residues on the cover layer or the coating.

A further advantage of using deionised water as an electrolytic liquid or as an auxiliary electrolyte is that distilled water can be used by a maintenance engineer in a simple manner and furthermore does not present any health risks to the maintenance engineer.

In a possible embodiment of the method according to the invention, the electrically conductive, flexible bristles are attached to a brush which is brushed over the surface of the electrically insulating cover layer.

In one embodiment of the method according to the invention, the electrically conductive, flexible bristles consist of electrically conductive polymers, metal fibres or natural bristles, the natural bristles receiving their conductivity by means of the auxiliary electrolytes, for example by means of deionised water.

In a possible embodiment of the method according to the invention, a temporal amplitude variation of the output measurement signal is detected and a coating error is recognised when an amplitude change exceeds an adjustable amplitude threshold value.

In a further embodiment of the method according to the invention, a phase shift is detected between the current and voltage of the output measurement signal and a coating error is recognised when a phase change exceeds an adjustable phase threshold value.

In a further embodiment of the method according to the invention, a charge and/or discharge time of an RC member with a capacitor, the capacitance of which is influenced by the layer thickness of the cover layer, is detected and a coating error is recognised when a charge and/or discharge time change exceeds an adjustable time period threshold value.

In a possible embodiment of the method according to the invention, the electrically conductive substrate layer comprises a carbon fibre-reinforced plastics material, metal or a semiconductor material.

In a possible embodiment of the method according to the invention, the electrically insulating cover layer has a protective lacquer.

In a further embodiment of the method according to the invention, the thickness of the cover layer and size of a coating error are calculated as a function of a signal parameter change.

The invention furthermore provides a measuring arrangement for the non-destructive detection of coating errors in an electrically conductive substrate layer, which is coated with at least one electrically insulating cover layer, comprising:
a) a signal input device for inputting an input signal into the substrate layer;
b) a signal output device for outputting a measurement signal from the substrate layer via the cover layer; and
c) an evaluation unit for evaluating the output measurement signal, a coating error being detected when a signal parameter change of a signal parameter of the output measurement signal exceeds an adjustable threshold value.

In one possible embodiment of the measuring arrangement according to the invention, the signal input device inputs the input signal inductively or capacitively into the substrate layer.

In a possible embodiment of the measuring arrangement according to the invention, the signal output device outputs the measurement signal inductively or capacitively from the substrate layer via the cover layer.

In a possible embodiment of the measuring arrangement according to the invention, the signal output device has flexible and electrically conductive bristles.

In one embodiment of the measuring arrangement according to the invention, the signal output device has a reservoir for receiving an electrolytic liquid, which is provided to moisten the bristles.

In one embodiment of the measuring arrangement according to the invention, the electrolytic liquid comprises distilled water or deionised water.

In one embodiment of the measuring arrangement according to the invention, the signal output device has a motor, which moves the signal output device over the surface of the cover layer in order to scan the cover layer to detect coating errors.

In one embodiment of the measuring arrangement according to the invention, the spatial coordinates of the movable signal output device are stored together with the signal parameters of the measurement signal in a memory to evaluate them.

In a possible embodiment of the measuring arrangement according to the invention, the latter has a microprocessor.

In a possible embodiment of the measuring arrangement according to the invention, the signal input device has an electrically conductive suction cup, a conductive foam rubber, a conductive roll or a conductive roller.

In a possible embodiment of the measuring arrangement according to the invention, the signal input device is attached, for the purpose of measurement, to the cover layer to be insulated or on the electrically conductive substrate layer.

The invention furthermore provides a computer program with program commands to carry out a method for the non-destructive detection of coating errors in an electrically conductive substrate layer, which is coated with at least one electrically insulating cover layer, comprising the steps:
a) inputting an input signal into the substrate layer;
b) outputting a measurement signal from the substrate layer via the cover layer; and
c) detecting a coating error when a signal parameter change of a signal parameter of the output measurement signal exceeds an adjustable threshold value.

The invention furthermore provides a data carrier, which stores a computer program of this type.

The invention furthermore provides a data carrier, which stores the measurement results obtained by the method according to the invention.

Preferred embodiments of the method according to the invention and of the measuring arrangement according to the invention for the non-destructive detection of coating errors will be described below with reference to the accompanying figures, in which:

### BRIEF DESCRIPTION OF THE DRAWINGS

FIG. 1A, 1B shows embodiments of the measuring arrangement according to the invention for the non-destructive detection of coating errors;

FIG. 2 shows various types of detectable coating errors to explain the measuring method according to the invention;

FIG. 3 shows a further view of a measuring arrangement according to the invention;

FIG. 4 shows a further block diagram to show a further embodiment of the measuring arrangement according to the invention;

FIG. 5 shows an embodiment of a measuring arrangement according to the invention;

FIG. 6 shows a further embodiment of a measuring arrangement according to the invention;

FIG. 7 shows a simple flow chart of an embodiment of the method according to the invention for the non-destructive detection of coating errors;

FIG. 8 shows a graph to illustrate an exemplary measuring result of the method according to the invention.

### DESCRIPTION OF EXEMPLARY EMBODIMENTS

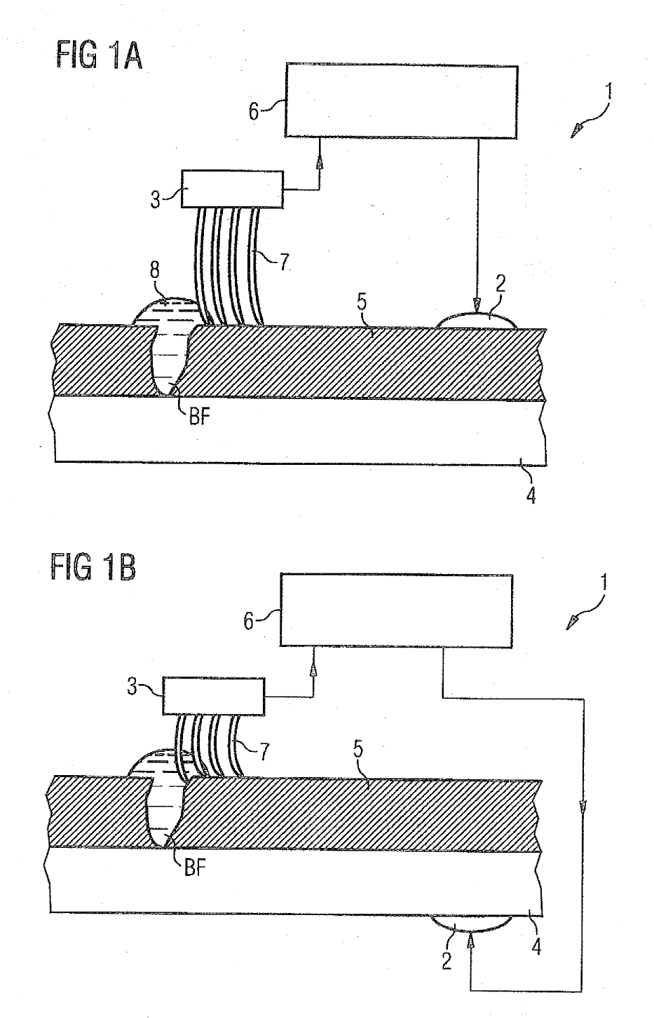

As can be seen in FIGS. 1A, 1B, a measuring arrangement 1 according to the invention for the non-destructive detection of coating errors BF contains a signal input device 2 and a signal output device 3. The measuring arrangement 1 detects coating errors in an electrically conductive substrate layer 4, which is coated with at least one electrically insulating cover layer 5. The electrically conductive substrate layer 4 may consist of a carbon fibre-reinforced plastics material. In an alternative embodiment, the electrically conductive substrate layer 4 consists of a metal or of a semiconductor material. The electrically insulating cover layer 5, for example, consists of a protective lacquer. In a possible embodiment, this protective lacquer is a corrosion inhibitor.

As can be seen in FIGS. 1A, 1B, the signal input device 2 for inputting an input signal into the substrate layer 4 and the signal output device 3 for outputting a measurement signal from the substrate layer 4 are connected to a unit 6, which is provided, on the one hand, to generate the input signal and, on the other hand, to evaluate the measurement signal supplied by the signal output device 3.

The signal input device 2 inputs the input signal generated by the unit 6 inductively or capacitively into the electrically conductive substrate layer 4. In the embodiment shown in FIG. 1A, a capacitive input into the electrically conductive substrate layer 4 takes place across the electrically insulating cover layer 5. In the embodiment shown in FIG. 1B, the input of the input signal, on the other hand, takes place directly into the electric substrate layer 4. The embodiment shown in FIG. 1A of a capacitive input of the input signal via the cover layer 5 has the advantage that no direct contact has to be made with the electrically conductive substrate layer 4. This is particularly advantageous when the electrically conductive layer 4 is completely surrounded by an insulating cover layer 5 and direct electric contact cannot be made with the substrate layer 4 without damaging the electrically insulating cover layer 5.

In a possible embodiment, the signal input device 2 has an electrically conductive suction cup which, as shown in FIG. 1A, is placed on the electrically insulating cover layer 5 or, as shown in FIG. 1B, is attached directly to the electrically conductive layer 4.

In an alternative embodiment, the signal input device 2 is, for example, a conductive foam rubber. In a further embodiment, the signal input device 2 consists of a conductive roll or a conductive roller.

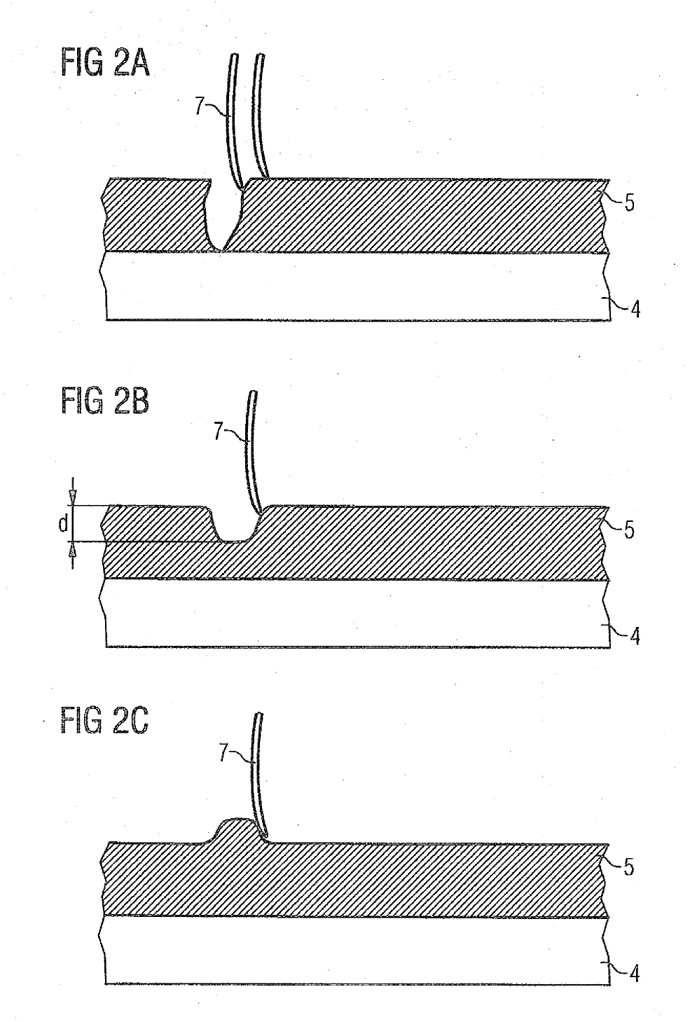

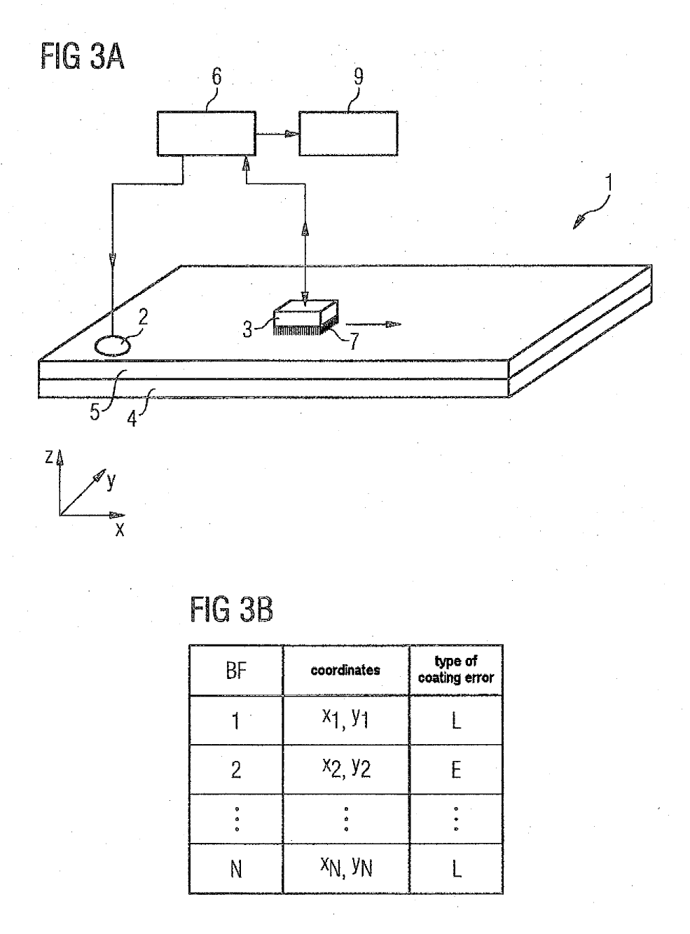

The electrically insulating cover layer 5 shown in FIGS. 1A, 1B has a coating error BF. In the example shown, the coating error BF is a hole, which extends through to the substrate layer 4. Further types of coating error are possible, as explained in conjunction with FIGS. 2A, 2B, 3C. To detect the coating error BF using the signal output device 3, the measurement signal input into the electrically conductive substrate layer 4 is output and then evaluated by the evaluation unit 6. The measurement signal can in turn be output inductively or capacitively.

In the embodiments shown in FIGS. 1A, 1B, the signal output device 3 has electrically conductive flexible bristles 7, which may be attached to a brush. This brush is brushed over the surface of the electrically insulating cover layer 5, as schematically shown in FIGS. 1A, 1B. The input measurement signal is output by means of the flexible and electrically conductive bristles and supplied to the evaluation unit 6. The evaluation unit 6 evaluates the output measurement signal, a coating error BF being detected when a signal parameter change of at least one signal parameter of the output measurement signal exceeds an adjustable place value. As shown in FIG. 1A, 1B, the flexible, electrically conductive bristles 7 of the signal output device 3 or the surface of the cover layer 5 are moistened with an electrolytic liquid 8. This electrolytic liquid 8 forms an auxiliary electrolyte, which is electrically conductive. In a possible embodiment, the electrolytic liquid is formed by deionised water or even distilled water. A possible course of action is to moisten the bristles 7 of the signal output device 3 with the auxiliary electrolyte or the electrolytic liquid and to then guide the brush or the signal output device 3 with the moistened bristles 7 over the surface of the cover layer 5. As soon as one or more of the bristles 7 are moved over a coating error, this produces a signal parameter change of the output measurement signal, which is detected by the evaluation unit 6. Moreover, in a possible embodiment, the type of coating error BF can also be inferred on the basis of the signal parameter change.

In a possible embodiment, a temporal amplitude variation of the output measurement signal is detected and a coating error BF recognised when an amplitude change AA exceeds an adjustable amplitude threshold value.

In an alternative embodiment, a phase shift between a current and voltage signal of the output measurement signal is detected by the evaluation unit 6 and a coating error BF is recognised when a phase change Δφ exceeds an adjustable phase threshold value.

In a further embodiment, a charge and/or discharge time of an RC member, which contains a capacitor, the capacitance of which is influenced by the layer thickness of the cover layer 5, is detected by the evaluation unit 6 and a coating error BF is recognised when a charge and/or a discharge time change exceeds an adjustable time period threshold value.

The signal parameter change also permits the type and extent of a coating error BF to be recognised. FIG. 2A, 2B, 2C show various detectable types of coating error. The type of coating error shown in FIG. 2A is a hole which is present in the cover layer 5 and extends through to the electrically conductive substrate layer 4. The hole schematically shown in FIG. 2A may be a very small hole or a crack, it being possible for the spatial extent of a hole or crack of this type to be larger or smaller than the diameter of a bristle 7.

The coating error BF shown in FIG. 2B is a hole in the cover layer 5 which does not extend through to the substrate layer 4. A coating error of this type can also be detected by the measuring method according to the invention as the capacitance is significantly increased at the point of the coating error BF. This is because the spacing between the electrically conductive substrate layer 4 of the moistened bristle 7 is smaller at the point of the coating error than at the remaining points. As the capacitance C of a capacitor is inversely proportional to the spacing d of its boards, the capacitance C at the point of the coating error BF shown in FIG. 2B is significantly increased:

$$C = {ɛ}_{0} {ɛ}_{r} \cdot \frac{A}{d}$$

FIG. 2C shows a further type of coating error, in which the cover layer 5 has an undesired elevation as the coating error. In the example shown in FIG. 2C, the capacitance C drops at the point of the coating error BF.

FIG. 3A schematically shows an embodiment of a measuring arrangement 1 according to the invention. The signal output device 3 with the conductive bristles 7 attached thereto reads out the measurement signal input by the signal input device 2 into the electrically conductive substrate layer 4 for evaluation.

In the embodiment shown in FIG. 3A, the signal output device 3 is integrated in a brush having a plurality of moistened bristles 7. This brush may be brushed, manually computer-controlled, over the surface of the cover layer 5 to detect coating errors BF in the cover layer 5. As soon as a signal parameter change of a signal parameter of the output measurement signal exceeds an adjustable threshold value, the coating error BF is output together with the coordinates of the coating error or stored in a memory 9. FIG. 3B shows, by way of example, a table of various detected coating error BF, with associated coordinates and further details or information about the coating error detected. These descriptive data may, for example, disclose the type of coating error BF, i.e. whether this is a hole (L) or an elevation (E). Furthermore, on the basis of the detected signal parameter changes, details about the dimensions of the coating error can be calculated and stored.

The brush shown in FIG. 3A is guided manually by a maintenance engineer over a cover layer 5, the coordinates x, y of the brush being determined in a possible embodiment by means of a wireless interface and triangulation.

FIG. 3A shows a simple component, namely a board with an electrically conductive substrate layer 4 and a cover layer 5. The extent of a board of this type may be several metres both in the x-direction and in the y-direction. The measuring method according to the invention is not at all restricted to simple boards with a simple surface, but is also suitable for other surfaces, in particular cylindrical hollow bodies.

In a possible embodiment, the brush shown in FIG. 3A additionally has a reservoir to receive an electrolytic liquid to moisten the bristles 7. The electrically conductive, flexible bristles 7 may consist of electrically conductive polymers, metal fibres or natural bristles. The natural bristles receive their conductivity by means of the auxiliary electrolytes.

In a possible embodiment of the measuring method according to the invention, a coating error BF is not only detected, but is then also repaired automatically.

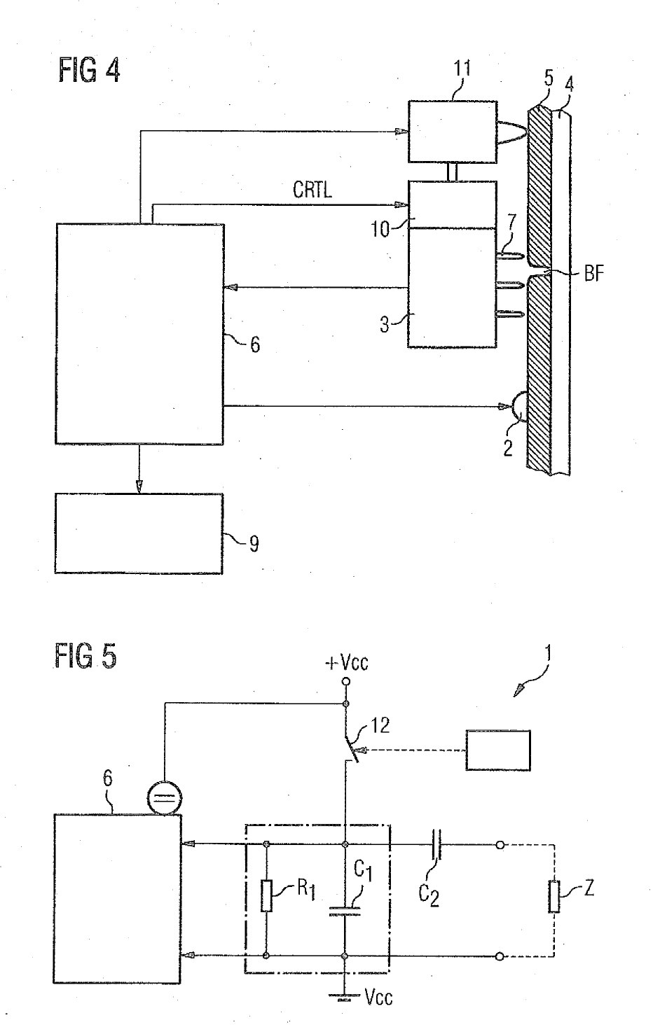

In the embodiment shown in FIG. 4, the unit 6 generates an input signal, which is capacitively input into the electrically conductive substrate layer 4 via the cover layer using a signal input device 2, for example an electrically conductive suction cup. The capacitively input measurement signal spreads out in the electrically conductive layer 4 and is supplied by the output device 3 to the unit 6 for signal evaluation. The coating error BF shown schematically in FIG. 4 is recognised when the bristles 7 are brushed over the coating error BF on the basis of a sufficiently large signal parameter change. The input signal may, for example, be a pulsed direct voltage signal. In an alternative embodiment, the input signal may be an alternating voltage signal with an adjustable frequency. In the embodiment shown in FIG. 4, the signal output device integrated in a brush is guided by a controlled motor 10 over the cover layer 5 to detect coating errors BF. A motor 10 is activated by a motor controller within the unit 6. For example, the brush is guided in a meandering manner over the entire surface of the cover layer 5 to detect coating errors BF. In the embodiment shown in FIG. 4, a repair unit 11, which automatically repairs a recognised coating error BF at the detected point, is provided on the brush driven by the motor 10. In this case, a hole detected in the cover layer 5 is filled in and an elevation detected in the cover layer 5 is removed by the repair unit 11.

FIG. 5 shows a further embodiment of the measuring arrangement 1 according to the invention. In the embodiment shown in FIG. 5, a charge or discharge time of an RC member with a capacitor, the capacitance of which is influenced by the layer thickness of the cover layer 5, is detected. A coating error BF is recognised when a charge and/or discharge time change exceeds an adjustable time period threshold value. A direct voltage of, for example, 5V is applied by means of a controlled switch 12 to the component to be measured, which has a complex resistance Z. By regularly switching the switch 12, a pulsed direct voltage signal is produced to charge and discharge an RC member. For example, the switch 12 is switched on and off 1,000 times per second. If the cover layer 5 is undamaged and therefore insulates well, the complex resistance Z is infinitely great. The time behaviour of the RC member depends on the resistance R1 and the capacitance C1. The resistance R1, for example, has a resistance of 1 Mohm and the capacitor C1 has a capacitance of 68 pF. If the surface to be measured has a coating error BF, the complex resistance Z changes. In the case of a continuous hole, a short circuit is caused between the signal input device and the signal output device so the capacitor C2 shown in FIG. 5 is connected in parallel to the RC member. The capacitor C2, for example, has a capacitance of 100 nF. Owing to the parallel connection of the capacitor C2, the charge and discharge time of the RC member is drastically increased. This change in the charge and discharge time is detected by a microprocessor contained in the evaluation unit 6.

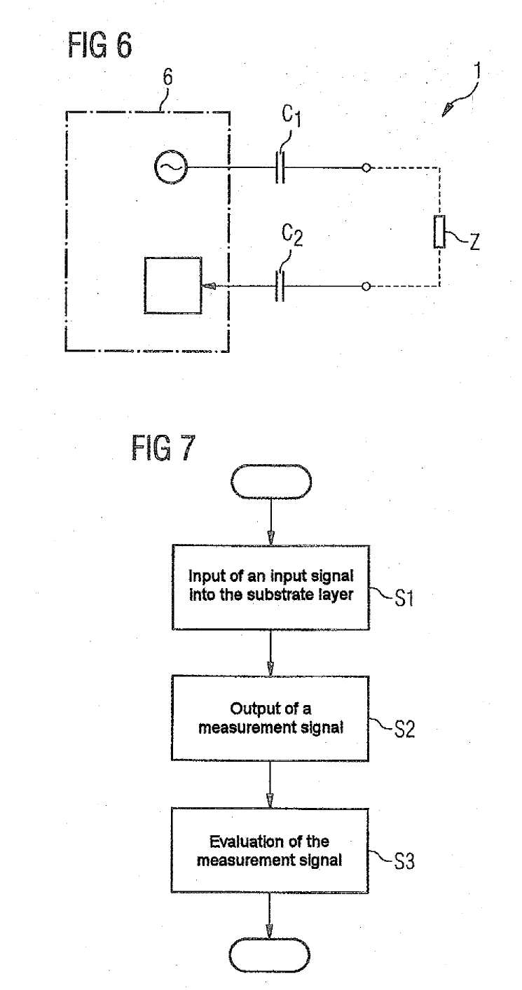

FIG. 6 shows a further embodiment of the measuring arrangement 1 according to the invention. In this case, by means of a signal generator contained in the unit 6, an alternating voltage signal with an adjustable signal frequency is capacitively input via a signal input device at the coated component and then capacitively output again via signal output device and evaluated. The signal input device is, for example, comprises an electrically conductive suction cup with a capacitance C1. The signal output device is, for example, comprises a wet brush or a moistened brush with a capacitance C2. The alternating voltage signal is, for example, a sinusoidal alternating voltage signal. The measurement signal sensor or the signal output device, which can be formed by a wet brush, together with an undamaged surface, for example, has a capacitance of about 100 pF. If the coated module is damaged, the resistance Z drops and this leads to an increase in the measured amplitude of the alternating voltage signal. This increase is detected by the evaluation unit 6. Further measuring variants are possible. For example, the surface to be investigated, in the undamaged state, i.e. without coating errors, is an almost ideal capacitor, which supplies a phase displacement of up to 90° between a measured current and a measured voltage signal. If the cover layer now has a local defect, this leads to a reduction in capacitance or there is no capacitance at all. This can result in a change in the phase angle to 0. This phase angle change Δφ can be detected by the evaluation unit 6.

FIG. 7 shows a simple flow chart of a possible embodiment of the measuring method according to the invention.

In a first step S1, an input signal is directly or indirectly input into the electrically conductive substrate layer 4. Inputting can take place capacitively or inductively, for example. In a possible embodiment, the input signal is a pulsed direct voltage signal. In an alternative embodiment, the input signal is an alternating voltage signal with an adjustable frequency.

In a further step S2, a measurement signal is output from the substrate layer 4 via the cover layer 5. The measurement signal can, in turn, be output inductively or capacitively.

In the further step S3, the output measurement signal is evaluated. In this case, a coating error is detected in the cover layer 5 when a signal parameter change of at least one signal parameter of the output measurement signal exceeds an adjustable threshold value. This adjustable threshold value may, for example, take into account the layer thickness of the cover layer 5. The measurement signal is output in step S2 at a locally variable point, a moistened brush or a brush with conductive bristles, for example, being moved over the surface of the cover layer 5 in order to receive the measurement signal.

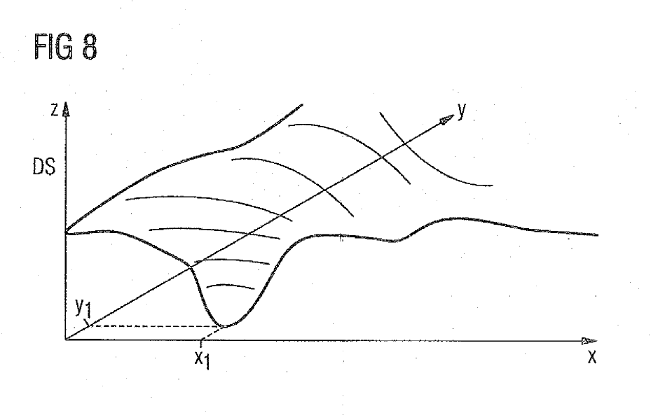

FIG. 8 schematically shows a measurement result of the measuring arrangement 1 according to the invention. The thickness of the cover layer 5 is stored, for example, as a height profile. In the embodiment shown, the cover layer at the point X1, Y1, has an indentation reaching through to the substrate layer 4.

The method according to the invention and the measuring arrangement 1 according to the invention can be used in a variety of ways. For example, coating errors in a carbon fibre-reinforced plastics material coated with a lacquer layer can be determined using the measuring arrangement 1 according to the invention. Carbon fibre-reinforced plastics materials of this type are used, for example, in aircraft construction or in vehicle construction. The measuring method according to the invention allows coating errors to be detected non-destructively on surfaces formed in any manner, the signal voltages used being small. These small signal voltages do not endanger the maintenance engineer. On the other hand, the cover layer to be investigated is not damaged either. A direct conductive electrical contact with the conductive substrate layer 4 is not required as the input takes place inductively or capacitively.

In a further variant of the measuring arrangement 1 according to the invention, the signal output device 3 is not moved over the cover layer 5, but the component to be measured is moved over a fixed-position signal output device 3.

In a further embodiment variant of the measuring arrangement 1 according to the invention, the signal transmission from/to the evaluation unit 6 takes place via the signal input and output device via a wireless interface. Moreover, the evaluation unit 6 may be connected via a network to a remote server and an associated database.

In a further embodiment variant of the measuring arrangement 1 according to the invention, not just one signal parameter of the received signal, but a plurality of signal parameters, for example the signal amplitude and a phase change, are evaluated. By evaluating a plurality of signal parameters, the precision in measuring the coating error BF can be increased, both with regard to the type and the size of the coating error.

In a possible embodiment variant, characteristics/desired values are input via a user interface. For example, a desired thickness of the cover layer 5 is input by a maintenance engineer and the desired value of a signal parameter is calculated from this. If the difference between the measured signal parameter and the expected desired value is greater than a threshold value that can be input, a coating error BF is detected.

The measuring arrangement 1 according to the invention can be used, for example, for quality assurance. In this case, limit values, for example desired values which, for example, ensure long-term protection, can be input and verified. As a result, in particular, the dangers and risks of corrosion damage are minimised. Quality assurance measures of this type can be specified and controlled. Moreover, the measuring arrangement 1 can already be installed by the component supplier. The measuring method according to the invention is suitable for detecting coating errors in any electrically conductive substrate layers 4, which are coated with an electrically insulating cover layer 5. The measuring arrangement 1 according to the invention is suitable, in particular, in the aerospace sector and in the automobile industry.

### LIST OF REFERENCE NUMERALS

1 measuring arrangement
2 signal input device
3 signal output device
4 substrate layer
5 cover layer
6 evaluation unit
7 bristles
8 electrolytic liquid
9 memory
10 motor
11 repair unit
12 switch
BF coating error
C capacitance
C1-C2 capacitor
Δφ phase angle change
E elevation
L hole
S1 input
S2 output
S3 detection

1. A measuring arrangement for the non-destructive detection of coating errors in an electrically insulating layer, with which an electrically conductive substrate is coated, comprising:
a) a signal input device for inputting an input signal into the conductive substrate via the electrically insulating layer;
b) a movable signal output device for outputting a measurement signal from the conductive substrate via the electrically insulating layer, wherein the movable signal output device has flexible and electrically conductive bristles;
c) and comprising an evaluation unit for evaluating the output measurement signal, a coating error of the electrically insulating layer being detected when a signal parameter change of a signal parameter of the output measurement signal exceeds an adjustable threshold value.

2. The measuring arrangement according to claim 1, wherein the signal output device has a reservoir to receive an electrolytic liquid, which is provided to moisten the bristles.

3. The measuring arrangement according to claim 2, wherein the electrolytic liquid comprises water or deionised water.

4. The measuring arrangement according to claim 1, wherein the signal input device has an electrically conductive suction cup, a conductive foam rubber, a conductive roll or a conductive roller.

5. The measuring arrangement according to claim 4, wherein the signal input device is attached to the layer to be insulated for the purpose of measurement.

6. The measuring arrangement according to claim 1, wherein the signal input device inductively or capacitively inputs the input signal into the conductive substrate.

7. The measuring arrangement according to claim 6, wherein the signal output device inductively or capacitively outputs the measurement signal from the substrate via the electrically insulating layer.

8. The measuring arrangement according to claim 1, wherein the movable signal output device has a motor, which moves the signal output device over the surface of the electrically insulating layer in order to scan the electrically insulating layer to recognise coating errors.

9. The measuring arrangement according to claim 8, wherein the spatial coordinates of the movable signal output device are stored together with the signal parameters of the measurement signal in a memory to evaluate them.

10. A method for the non-destructive detection of coating errors in at least one electrically insulating layer, with which an electrically conductive substrate is coated, comprising the steps:
a) inputting an input signal into the substrate via the electrically insulating layer;
b) outputting a measurement signal from the substrate layer via the electrically insulating layer (5) and via flexible and electrically conductive bristles;
c) detecting coating errors of the electrically insulating layer when a signal parameter change of a signal parameter of the output measurement signal exceeds an adjustable threshold value.

11. The method according to claim 10, wherein the input signal is input capacitively or inductively into the electrically conductive substrate.

12. The method according to claim 10, wherein the input signal is formed by a pulsed direct voltage signal or by an alternating voltage signal with an adjustable frequency.

13. The method according to claim 10, wherein the coordinates and type of coating error of a detected coating error are established.

14. The method according to claim 13, wherein the respective coating error is then automatically repaired as a function of the recognised type of coating error.

15. The method according to claim 10, wherein a temporal amplitude variation of the output measurement signal is detected and a coating error of the electrically insulating layer is recognised when an amplitude change exceeds an adjustable amplitude threshold value.

16. The method according to claim 10, wherein a phase shift between the current and voltage of the output measurement signal is detected and a coating error of the electrically insulating layer is recognised when a phase change exceeds an adjustable phase threshold value.

17. The method according to claim 10, wherein a charge and/or discharge time of an RC member with a capacitor, the capacitance of which is influenced by the layer thickness of the electrically insulating layer, is detected and a coating error of the electrically insulating layer is recognised when a charge and/or discharge time change exceeds an adjustable time period threshold value.

18. The method according to claim 10, wherein the thickness of the electrically insulating layer and size of a coating error are calculated as a function of the signal parameter change.
